(19) United States
(12) Patent Application Publication
(10) Pub. No.: US 2025/0221280 A1
(43) Pub. Date: Jul. 3, 2025

(54) Display Apparatus Having a Light-Emitting Device and a Pixel Lens

(71) Applicant: LG Display Co., Ltd., Seoul (KR)

(72) Inventors: Se Wan Oh, Paju-si (KR); Yoon Ji Choi, Paju-si (KR); Seok Ho Ki, Paju-si (KR)

(21) Appl. No.: 18/969,076

(22) Filed: Dec. 4, 2024

(30) Foreign Application Priority Data
Dec. 28, 2023 (KR) 10-2023-0194731

(51) Int. Cl. H10K 59/80; H10K 59/40

(52) U.S. Cl. CPC H10K 59/879; H10K 59/40; H10K 59/873

(57) ABSTRACT

A display apparatus in which a light-emitting device and a pixel lens are disposed in each pixel area is provided. An encapsulation structure can be disposed between the light-emitting device and the pixel lens of each pixel area. A lens passivation layer covering the pixel lenses and a lens dam surrounding the lens passivation layer can be disposed on the encapsulation structure. The lens dam can include a first region having a first width and a second region having a second width different from the first width. Thus, in the display apparatus, loss and deformation of the lens dam due to a process of forming the pixel lenses and/or the lens passivation layer can be prevented. Therefore, in the display apparatus, damage of the pixel lenses due to external impact and moisture can be effectively prevented.

### CROSS-REFERENCE TO RELATED APPLICATIONS

This application claims the benefit of Republic of Korea Patent Application No. 10-2023-0194731, filed on Dec. 28, 2023, which is hereby incorporated by reference as if fully set forth herein.

### BACKGROUND

### Field

The present disclosure relates to a display apparatus in which a light-emitting device and a pixel lens are disposed in each pixel area.

### Discussion of the Related Art

Generally, a display apparatus provides an image to a user. For example, the display apparatus can include light-emitting devices disposed on pixel areas. Each of the light-emitting devices can emit light displaying a specific color. For example, each of the light-emitting devices can include a first electrode, a light-emitting unit and a second electrode, which are sequentially stacked on a device substrate.

Pixel lenses overlapping with the light-emitting devices can be disposed on the pixel areas. For example, the light emitted from the light-emitting device of each pixel area can be emitted outside through the pixel lens of the corresponding pixel area. The pixel lenses can be disposed on an encapsulation structure covering the light-emitting devices. A lens passivation layer covering the pixel lenses can be disposed on the encapsulation structure.

The lens passivation layer can prevent damage of the pixel lenses due to external impact. The lens passivation layer can include a material having high fluidity. For example, a process of forming the pixel lenses and a process of forming the lens passivation layer can include an ink-jet process. At least one lens dam to block flow of the lens passivation layer can be formed on the encapsulation structure. For example, the lens dam can surround the lens passivation layer.

At least some of processes of forming the pixel lenses can be performed after formation of the lens dam. Thus, in the display apparatus, at least some of the lens dam can be lost or deformed by a process of forming the pixel lenses and/or the lens passivation layer according to adhesive between the lens dam and a lower layer of the lens dam. That is, in the display apparatus, some of pixel lenses cannot be covered by the lens passivation layer, completely. Therefore, in the display apparatus, a surface of some of the pixel lenses can be damaged by the external impact.

### SUMMARY

Accordingly, the present disclosure is directed to a display apparatus that substantially obviates one or more problems due to limitations and disadvantages of the related art.

An object of the present disclosure is to provide a display apparatus capable of preventing the damage of the pixel lenses due to the external impact.

Another object of the present disclosure is to provide a display apparatus capable of preventing loss and deformation of the lens dam due to a process of forming the pixel lenses and the lens passivation layer.

Additional advantages, objects, and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

To achieve these objects and other advantages and in accordance with the purpose of the present disclosure, as embodied and broadly described herein, there is provided a display apparatus comprising a device substrate. A light-emitting device and an encapsulation structure are disposed on the device substrate. The light-emitting device is disposed on a pixel area of the device substrate. The encapsulation structure covers the light-emitting device. A pixel lens, a lens passivation layer and a first lens dam are disposed on the encapsulation structure. The pixel lens overlaps the pixel area. The lens passivation layer covers the pixel lens. The first lens dam surrounds the lens passivation layer. The first lens dam includes a first dam region, a second dam region and a third dam region. The third dam region is disposed between the first dam region and the second dam region. The first dam region and the second dam region have a bar shape extending in a first direction. A length of the third dam region in a second direction perpendicular to the first direction is greater than a length of the first dam region in the second direction and a length of the second dam region in the second direction.

The third dam region can include a same material as the first dam region and the second dam region.

A length of the third dam region in the first direction can be different from a length of the first dam region in the first direction and a length of the second dam region in the first direction.

The length of the second dam region in the first direction can be a same as the length of the first dam region in the first direction.

The length of the third dam region in the first direction can be a same as the length of the first dam region in the second direction and the length of the second dam region in the second direction.

The second dam region can be arranged alternately with the first dame region in the second direction.

At least one groove can be disposed at an upper surface of the first lens dam opposite to the device substrate.

A second lens dam can be disposed on the encapsulation structure. The second lens dam can extend parallel to the first lens dam.

In another embodiment, there is provided a display apparatus comprising a device substrate. The device substrate includes an active area and a bezel area. Light-emitting devices are disposed on pixel areas of the active area. The light-emitting devices are covered by an encapsulation structure. Pixel lenses, a lens dam and a lens passivation layer are disposed on the encapsulation structure. The pixel lenses overlap the pixel areas. The lens dam is disposed on the bezel area. The lens dam surrounds the active area. The lens passivation layer is disposed in a region defined by the lens dam. The lens passivation layer covers the pixel lenses. A first side of the lens dam toward the active area has a concave-convex shape.

The lens dam can include a same material as the pixel lenses.

The lens dam can include a second side opposite to the first side. The second side of the lens dam can have a concave-convex shape.

The second side of the lens dam can be a shape symmetrical to the first side of the lens dam.

At least one barrier pattern can be disposed between the encapsulation structure and the pixel lenses. An emission area can be defined in each pixel area. The barrier pattern cannot overlap the emission area of each pixel area.

A touch sensor can be disposed between the encapsulation structure and the pixel lenses. The touch sensor can include touch electrodes. The touch electrodes can overlap the barrier pattern.

At least one lens spacer can be disposed between the pixel lenses. The lens spacer can overlap the barrier pattern.

The lens dam can include first dam regions and second dam regions disposed between the first dam regions.

The first dam regions can have a bar shape extending in a first direction. At both sides of the second dam region, an upper surface of the lens dam opposite to the device substrate can have grooves disposed side by side in the first direction.

The second dam regions can have a bar shape extending in a second direction perpendicular to the first direction. A size of the second dam region can be the same as a size of the first dam region.

A thickness of the second dam region can be greater than a thickness of the first dam region.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure.

FIG. 1 is a view schematically showing a display apparatus according to an embodiment of the present disclosure.

FIG. 2 is a view showing a circuit of a pixel area in the display apparatus according to the embodiment of the present disclosure.

FIG. 3 is a view showing a cross-section of the pixel area in the display apparatus according to the embodiment of the present disclosure.

FIG. 4 is a view taken along I-I′ of FIG. 1 according to an embodiment.

FIG. 5 is a view showing a plane shape of a lens dam before and after a reflow process in a display apparatus according to the embodiment of the present disclosure.

FIG. 6 is a view taken along II-II′ of FIG. 5 according to an embodiment.

FIGS. 7 to 19 are views showing the display apparatus according to another embodiment of the present disclosure.

### DETAILED DESCRIPTION

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure can be embodied in other forms and is not limited to the embodiments described below.

In addition, the same or extremely similar elements can be designated by the same reference numerals throughout the specification and in the drawings, the lengths and thickness of layers and regions can be exaggerated for convenience. It will be understood that, when a first element is referred to as being “on” a second element, although the first element can be disposed on the second element so as to come into contact with the second element, a third element can be interposed between the first element and the second element.

Here, terms such as, for example, “first” and “second” can be used to distinguish any one element with another element. However, the first element and the second element can be arbitrary named according to the convenience of those skilled in the art without departing the technical sprit of the present disclosure.

The terms used in the specification of the present disclosure are merely used in order to describe particular embodiments and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” can include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### Embodiment

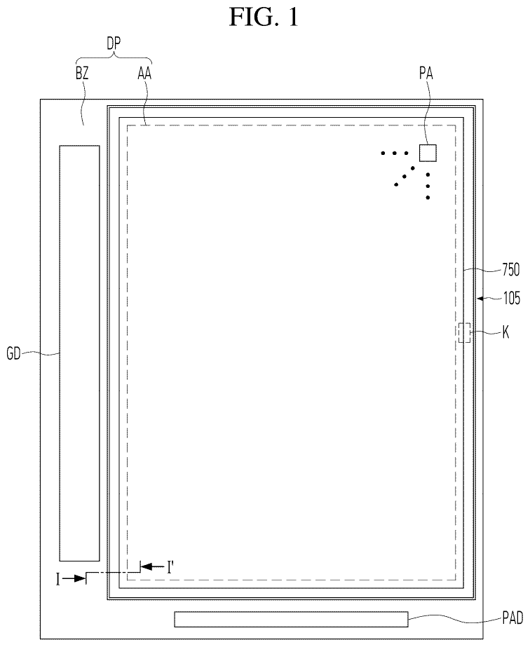

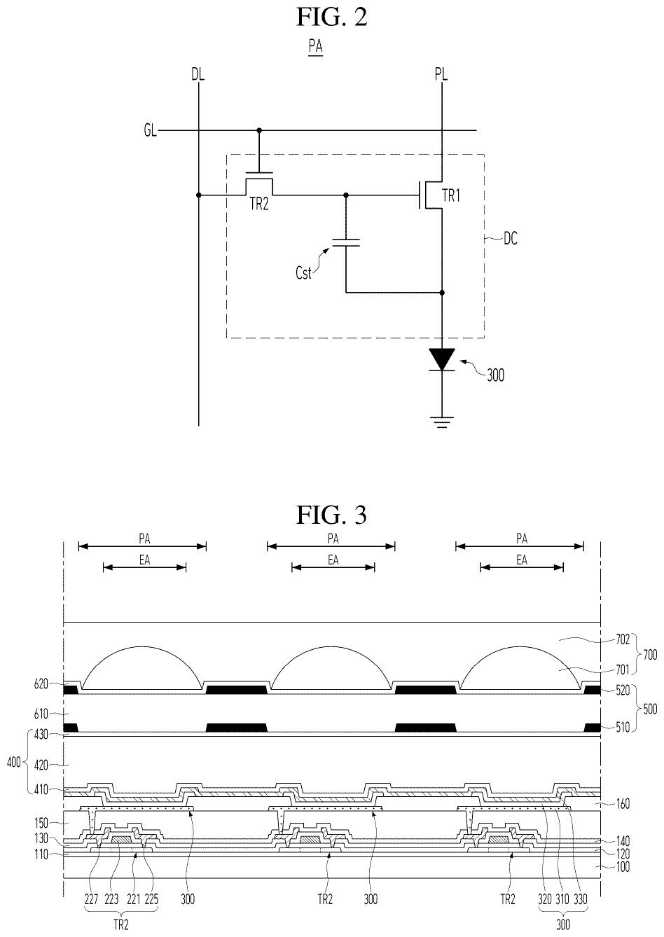

FIG. 1 is a view schematically showing a display apparatus according to an embodiment of the present disclosure. FIG. 2 is a view showing a circuit of a pixel area in the display apparatus according to the embodiment of the present disclosure.

Referring to FIGS. 1 and 2, the display apparatus according to the embodiment of the present disclosure can include a display panel DP. The display panel DP can generate an image provided to a user. For example, a plurality of pixel areas PA can be disposed in the display panel DP. Various signals can be provided in each pixel area PA through signal wirings GL, DL and PL. For example, the signal wirings GL, DL and PL can include gate lines GL sequentially applying a gate signal, data lines DL applying a data signal, and power voltage supply lines PL supplying a power voltage. The gate lines GL can be electrically connected to a gate driver GD. The data lines DL can be electrically connected to a data driver. The power voltage supply lines PL can be electrically connected to a power unit. The gate driver GD and the data driver can be controlled by a timing controller. For example, the gate driver GD can receive clock signals, reset signals and a start signal from the timing controller, and the data driver can receive digital video data and a source timing signal from the timing controller.

The display panel DP can include an active area AA in which the pixel areas PA are disposed, and a bezel area BZ being disposed outside the active area AA. The bezel area BZ can be disposed outside the pixel areas PA. For example, the active area AA can be surrounded by the bezel area BZ. The gate driver GD, the data driver, the power unit and the timing controller can be disposed outside the active area AA. For example, each of the signal wirings GL, DL and PL can include a region disposed on the bezel area BZ.

At least one of the gate driver GD, the data driver, the power unit and the timing controller can be disposed on the bezel area BZ. For example, the display apparatus according to the embodiment of the present disclosure can be a GIP (Gate In Panel) type display apparatus in which the gate driver GD is formed on the bezel area BZ of the display panel DP. The data driver, the power unit and the timing controller can be disposed outside the display panel DP. A pad portion PAD that an external signal is applied can be disposed in the bezel area BZ of the display panel DP. For example, the data lines DL can be connected to the data driver by the pad portion PAD.

Each of the pixel areas PA can realize a specific color. For example, a driving circuit DC electrically connected to a light-emitting device 300 can be disposed in each pixel area PA. The driving circuit DC of each pixel area PA can control the light-emitting device 300 of the corresponding pixel area PA according to signals applied to the signal wirings GL, DL and PL. For example, the driving circuit DC of each pixel area PA can be electrically connected to one of the gate lines GL, one of the data lines DL, and one of the power voltage supply lines PL. The driving circuit DC of each pixel area PA can supply a driving current corresponding to the data signal to the light-emitting device 300 of the corresponding pixel area PA according to the gate signal for one frame. For example, the driving circuit DC of each pixel area PA can include a first thin film transistor TR1, a second thin film transistor TR2 and a storage capacitor Cst.

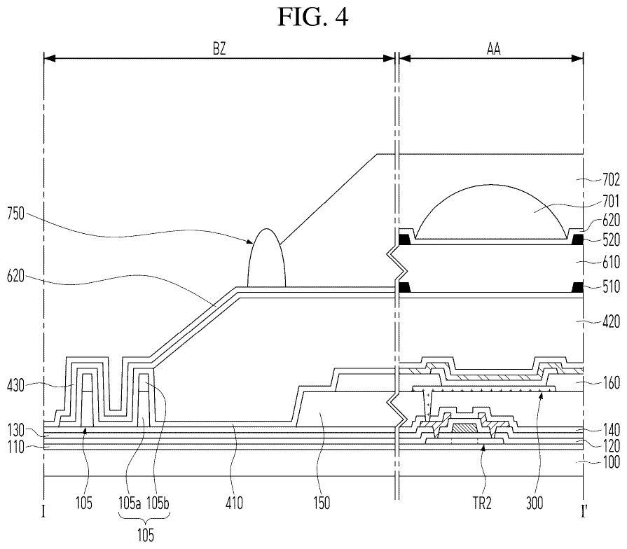

FIG. 3 is a view showing a cross-section of the pixel area in the display apparatus according to the embodiment of the present disclosure. FIG. 4 is a view taken along I-I′ of FIG. 1 according to an embodiment.

Referring to FIGS. 2 to 4, the first thin film transistor TR1 can transmit the data signal to the second thin film transistor TR2 according to the gate signal. For example, the first thin film transistor TR1 can function as a switching thin film transistor. The first thin film transistor TR1 can include a first semiconductor pattern, a first gate electrode, a first drain electrode and a first source electrode. For example, the first gate electrode can be electrically connected to the corresponding gate line GL, and the first drain electrode can be electrically connected to the corresponding date line DL.

The first semiconductor pattern can include a semiconductor material. For example, the first semiconductor pattern can include amorphous silicon (a-Si), polycrystalline silicon (poly-Si) or an oxide semiconductor, such as IGZO. The first semiconductor pattern can include a first drain region, a first channel region and a first source region. The first channel region can be disposed between the first drain region and the first source region. A resistance of the first drain region and a resistance of the first source region can be a smaller that a resistance of the first channel region. For example, the first drain region and the first source region can include a conductive region of an oxide semiconductor. The first channel region can be a region of an oxide semiconductor, which is not conductorized.

The first gate electrode can be disposed on a portion of the first semiconductor pattern. For example, the first gate electrode can overlap the first channel region of the first semiconductor pattern. The first drain region and the first source region of the first semiconductor pattern can be disposed outside the first gate electrode. The first gate electrode can include a conductive material. For example, the first gate electrode can include a metal, such as aluminum (Al), chrome (Cr), copper (Cu), molybdenum (Mo), titanium (Ti) and tungsten (W). The first gate electrode can be spaced apart from the first semiconductor pattern. The first gate electrode can be insulated from the first semiconductor pattern. For example, the first drain region of the first semiconductor pattern can be electrically connected to the first source region of the first semiconductor pattern according to a signal applied to the first gate electrode.

The first drain electrode can include a conductive material. For example, the first drain electrode can include a metal, such as aluminum (Al), chrome (Cr), copper (Cu), molybdenum (Mo), titanium (Ti) and tungsten (W). The first drain electrode can include a different material from the first gate electrode. For example, the first drain electrode can be disposed on a different layer from the first gate electrode. The first drain electrode can be electrically connected to the first drain region of the first semiconductor pattern. The first drain electrode can be insulated from the first gate electrode.

The first source electrode can include a conductive material. For example, the first source electrode can include a metal, such as aluminum (Al), chrome (Cr), copper (Cu), molybdenum (Mo), titanium (Ti) and tungsten (W). The first source electrode can include a different material from the first gate electrode. The first source electrode can be disposed on a different layer from the first gate electrode. For example, the first source electrode can be disposed on a same layer as the first drain electrode. The first source electrode can include a same material as the first drain electrode. The first source electrode can be formed by a same process as the first drain electrode. For example, the first source electrode can be formed simultaneously with the first drain electrode. The first source electrode can be electrically connected to the first source region of the first semiconductor pattern. The first source electrode can be insulated from the first gate electrode. The first source electrode can be spaced apart from the first drain electrode.

The second thin film transistor TR2 can generate the driving current corresponding to the data signal. For example, the second thin film transistor TR2 can function as a driving thin film transistor. The second thin film transistor TR2 of each pixel area PA can include a second semiconductor pattern 221, a second gate electrode 223, a second drain electrode 225 and a second source electrode 227. For example, the second gate electrode 223 can be electrically connected to the first source electrode, and the second drain electrode 225 can be electrically connected to the corresponding power voltage supply line PL.

The second semiconductor pattern 221 can include a semiconductor material. For example, the second semiconductor pattern 221 can include amorphous silicon (a-Si), polycrystalline silicon (poly-Si) or an oxide semiconductor, such as IGZO. The second semiconductor pattern 221 can be disposed on a same layer as the first semiconductor pattern. The second semiconductor pattern 221 can include a same material as the first semiconductor pattern. The second semiconductor pattern 221 can be formed by a same process as the first semiconductor pattern. For example, the second semiconductor pattern 221 can be formed simultaneously with the first semiconductor pattern.

The second semiconductor pattern 221 can include a second drain region, a second channel region and a second source region. The second channel region can be disposed between the second drain region and the second source region. The second drain region and the second source region can have a smaller resistance than the second channel region. For example, the second drain region and the second source region can include a conductive region of an oxide semiconductor. The second channel region can be a region of an oxide semiconductor, which is not conductorized.

The second gate electrode 223 can be disposed on a portion of the second semiconductor pattern 221. For example, the second gate electrode 223 can overlap the second channel region of the second semiconductor pattern 221. The second drain region and the second source region of the second semiconductor pattern 221 can be disposed outside the second gate electrode 223. The second gate electrode 223 can include a conductive material. For example, the second gate electrode 223 can include a metal, such as aluminum (Al), chrome (Cr), copper (Cu), molybdenum (Mo), titanium (Ti) and tungsten (W). The second gate electrode 223 can be spaced apart from the second semiconductor pattern 221. The second gate electrode 223 can be insulated from the second semiconductor pattern 221. For example, the second channel region of the second semiconductor pattern 221 can have an electrical conductivity corresponding to a voltage applied to the second gate electrode 223.

The second drain electrode 225 can include a conductive material. For example, the second drain electrode 225 can include a metal, such as aluminum (Al), chrome (Cr), copper (Cu), molybdenum (Mo), titanium (Ti) and tungsten (W). The second drain electrode 225 can include a different material from the second gate electrode 223. For example, the second drain electrode 225 can be disposed on a different layer from the second gate electrode 223. The second drain electrode 225 can be electrically connected to the second drain region of the second semiconductor pattern 221. The second drain electrode 225 can be insulated from the second gate electrode 223.

The second drain electrode 225 can be disposed a same layer as the first drain electrode. The second drain electrode 225 can include a same material as the first drain electrode. The second drain electrode 225 can be formed by a same process as the first drain electrode. For example, the second drain electrode 225 can be formed simultaneously with the first drain electrode.

The second source electrode 227 can include a conductive material. For example, the second source electrode 227 can include a metal, such as aluminum (Al), chrome (Cr), copper (Cu), molybdenum (Mo), titanium (Ti) and tungsten (W). The second source electrode 227 can include a different material from the second gate electrode 223. The second source electrode 227 can be disposed on a different layer from the second gate electrode 223. For example, the second source electrode 227 can be disposed on a same layer as the second drain electrode 225. The second source electrode 227 can include a same material as the second drain electrode 225. The second source electrode 227 can be formed by a same process as the second drain electrode 225. For example, the second source electrode 227 can be formed simultaneously with the second drain electrode 225. The second source electrode 227 can be electrically connected to the second source region of the second semiconductor pattern 221. The second source electrode 227 can be insulated from the second gate electrode 223. The second source electrode 227 can be spaced apart from the second drain electrode 225.

The storage capacitor Cst can maintain a voltage applied to the second gate electrode 223 of the second thin film transistor TR2 for one frame. For example, the storage capacitor Cst can be electrically connected to the second gate electrode 223 and the second source electrode 227 of the second thin film transistor TR2. The storage capacitor Cst can have a stacked structure of capacitor electrodes. For example, the storage capacitor Cst can include a first capacitor electrode electrically connected to the second gate electrode 233, and a second capacitor electrode electrically connected to the second source electrode 227. The second capacitor electrode can be spaced apart from the first capacitor electrode.

The storage capacitor Cst can be formed by using a process of forming the first thin film transistor TR1 and the second thin film transistor TR2. For example, the first capacitor electrode can be disposed on a same layer as the second gate electrode 223, and the second capacitor electrode can be disposed on a same layer as the second source electrode 227. The first capacitor electrode can include a same material as the second gate electrode 223, and the second capacitor electrode can include a same material as the second source electrode 227. The first capacitor electrode can be formed by a same process as the second gate electrode 223, and the second capacitor electrode can be formed by a same process as the second source electrode 227. For example, the first capacitor electrode can be formed simultaneously with the second gate electrode 223, and the second capacitor electrode can be formed simultaneously with the second source electrode 227. Thus, in the display apparatus according to the embodiment of the present disclosure, a process of forming the driving circuit DC in each pixel area PA can be simplified.

The driving circuit DC and the light-emitting device 300 of each pixel area PA can be disposed on a device substrate 100. For example, the first thin film transistor TR1, the second thin film transistor TR2 and the storage capacitor Cst of each pixel area PA can be supported by the device substrate 100. The device substrate 100 can include an insulating material. For example, the device substrate 100 can include glass or plastic.

A plurality of insulating layers 110, 120, 130, 140, 150 and 160 for preventing unnecessary electrical connection can be disposed on the device substrate 100. For example, a buffer insulating layer 110, a gate insulating layer 120, an interlayer insulating layer 130, a device passivation layer 140, a planarization layer 150, and a bank insulating layer 160 can be disposed on the device substrate 100.

The buffer insulating layer 110 can be disposed close to the device substrate 100. The buffer insulating layer 110 can prevent pollution due to the device substrate 100 in a process of forming the driving circuit DC of each pixel area PA. For example, an upper surface of the device substrate 100 toward the driving circuit DC of each pixel area PA can be completely covered by the buffer insulating layer 110. The first thin film transistor TR1, the second thin film transistor TR2 and the storage capacitor Cst of each pixel area PA can be disposed on the buffer insulating layer 110. The buffer insulating layer 110 can include an insulating material. For example, the buffer insulating layer 110 can include an inorganic insulating material, such as silicon oxide (SiOx) and silicon nitride (SiNx). The buffer insulating layer 110 can have a multi-layer structure. For example, the buffer insulating layer 110 can have a stacked structure of an inorganic insulating layer made of silicon oxide (SiOx) and an inorganic insulating layer made of silicon nitride (SiNx).

The gate insulating layer 120 can be disposed on the buffer insulating layer 110. The first gate electrode of each pixel area PA can be insulated from the first semiconductor pattern of the corresponding pixel area PA by the gate insulating layer 120. The second gate electrode 223 of each pixel area PA can be insulated from the second semiconductor pattern 221 of the corresponding pixel area PA by the gate insulating layer 120. For example, the gate insulating layer 120 can cover the first semiconductor pattern and the second semiconductor pattern 221 of each pixel area PA. The first gate electrode and the second gate electrode 223 of each pixel area PA can be disposed on the gate insulating layer 120. The gate insulating layer 120 can include an insulating material. For example, the gate insulating layer 120 can include an inorganic insulating material, such as silicon oxide (SiOx) and silicon nitride (SiNx).

The interlayer insulating layer 130 can be disposed on the gate insulating layer 120. The first drain electrode and the first source electrode of each pixel area PA can be insulated from the first gate electrode of the corresponding pixel area PA by the interlayer insulating layer 130. The second drain electrode 225 and the second source electrode 227 of each pixel area PA can be insulated from the second gate electrode 223 of the corresponding pixel area PA by the interlayer insulating layer 130. For example, the interlayer insulating layer 130 can cover the first gate electrode and the second gate electrode 223 of each pixel area PA. The first drain electrode, the first source electrode, the second drain electrode 225 and the second source electrode 227 of each pixel area PA can be disposed on the interlayer insulating layer 130. The interlayer insulating layer 130 can include an insulating material. For example, the interlayer insulating layer 130 can include an inorganic insulating material.

The device passivation layer 140 can be disposed on the interlayer insulating layer 130. The device passivation layer 140 can prevent damage of the driving circuit DC in each pixel area PA due to external impact and moisture. The device passivation layer 140 can extend along an upper surface of the driving circuit DC in each pixel area PA opposite to the device substrate 100. For example, the first drain electrode, the first source electrode, the second drain electrode 225 and the second source electrode 227 of each pixel area PA can be covered by the device passivation layer 140. The first drain electrode of each pixel area PA can be in direct contact with the first drain region of the corresponding pixel area PA by penetrating the gate insulating layer 120 and the interlayer insulating layer 130, and the first source electrode of each pixel area PA can be in direct contact with the first source region of the corresponding pixel area PA by penetrating the gate insulating layer 120 and the interlayer insulating layer 130. The second drain electrode 225 of each pixel area PA can be in direct contact with the second drain region of the corresponding pixel area PA by penetrating the gate insulating layer 120 and the interlayer insulating layer 130, and the second source electrode 227 of each pixel area PA can be in direct contact with the second source region of the corresponding pixel area PA by penetrating the gate insulating layer 120 and the interlayer insulating layer 130. The device passivation layer 140 can include an insulating material. For example, the device passivation layer 140 can be an inorganic insulating material.

The planarization layer 150 can be disposed on the device passivation layer 140. The planarization layer 150 can remove a thickness difference due to the driving circuit DC of each pixel area PA. For example, an upper surface of the planarization layer 150 opposite to the device substrate 100 can be a flat surface. The upper surface of the planarization layer 150 can be parallel to the upper surface of the device substrate 100. The planarization layer 150 can include an insulating material. The planarization layer 150 can include a different material from the device passivation layer 140. The planarization layer 150 can include a material having a relatively high fluidity. For example, the planarization layer 150 can include an organic insulating material.

The light-emitting device 300 of each pixel area PA can be disposed on the upper surface of the planarization layer 150. The light-emitting device 300 of each pixel area PA can emit light displaying a specific color. For example, the light-emitting device 300 of each pixel area PA can include a first electrode 310, a light-emitting unit 320 and a second electrode 330, which are sequentially stacked on the planarization layer 150 of the corresponding pixel area PA.

The first electrode 310 can include a conductive material. The first electrode 310 can include a material having a relatively high reflectance. For example, the first electrode 310 can include a metal, such as aluminum (Al) or silver (Ag). The first electrode 310 can have a multi-layer structure. For example, the first electrode 310 can have a structure in which a reflective electrode made of a metal is disposed between transparent electrodes made of a transparent conductive material, such as ITO and IZO.

The light-emitting unit 320 can generate light having luminance corresponding to a voltage difference between the first electrode 310 and the second electrode 330. For example, the light-emitting unit 320 can include at least one emission material layer (EML). The emission material layer can include an organic emission material, an inorganic emission material, or a hybrid emission material. For example, the display apparatus according to the embodiment of the present disclosure can be an organic light-emitting display apparatus including an organic emission material.

The light-emitting unit 320 can have a multi-layer structure. For example, the light-emitting unit 320 can include at least one of a hole injection layer (HIL), a hole transport layer (HTL), an electron transport layer (ETL) and an electron injection layer (EIL). Thus, in the display apparatus according to the embodiment of the present disclosure, efficiency of the light-emitting unit 320 can be improved.

The second electrode 330 can include a conductive material. The second electrode 330 can include a different material from the first electrode 310. A transmittance of the second electrode 330 can be greater than a transmittance of the first electrode 310. For example, the second electrode 330 can be a transparent electrode made of a transparent conductive material, such as ITO and IZO. Thus, in the display apparatus according to the embodiment of the present disclosure, the light generated by the light-emitting unit 320 can be emitted outside through the second electrode 330.

The bank insulating layer 160 can be disposed on the planarization layer 150. The bank insulating layer 160 can define an emission area EA in each pixel area PA. A portion of the first electrode 310 in each pixel area PA can be exposed by the bank insulating layer 160. For example, the bank insulating layer 160 can cover an edge of the first electrode 310 in each pixel area PA. The bank insulating layer 160 can include an insulating material. For example, the bank insulating layer 160 can be an organic insulating material. The bank insulating layer 160 can include a different material from the planarization layer 150.

The first electrode 310 of each pixel area PA can be electrically connected to the second thin film transistor TR2 of the corresponding pixel area PA. For example, the first electrode 310 of each pixel area PA can be in direct contact with the second source electrode 227 of the corresponding pixel area PA by penetrating the device passivation layer 140 and the planarization layer 150. The second source electrode 227 and the first electrode 310 of each pixel area PA can be electrically connected to each other at the outside of the emission area EA defined in the corresponding pixel area PA. For example, a portion of the first electrode 310 disposed in the emission area EA of each pixel area PA can be in direct contact with the upper surface of the planarization layer 150. The light-emitting unit 320 and the second electrode 330 of each pixel area PA can be stacked on a portion of the corresponding first electrode 310 exposed by the bank insulating layer 160. That is, in the display apparatus according to the embodiment of the present disclosure, the light-emitting unit 320 and the second electrode 330 of each pixel area PA can be stacked on a portion of the first electrode 310 overlapping with the emission area EA of the corresponding pixel area PA. Thus, in the display apparatus according to the embodiment of the present disclosure, luminance deviation according to the generating location of the light emitted from the emission area EA of each pixel area PA can be prevented.

A voltage applied to the second electrode 330 of each pixel area PA can be a same as a voltage applied to the second electrode 330 of adjacent pixel area PA. For example, the second electrode 330 of each pixel area PA can be electrically connected to the second electrode 330 of adjacent pixel area PA. The second electrode 330 of each pixel area PA can include a same material as the second electrode 330 of adjacent pixel area PA. The second electrode 330 of each pixel area PA can be formed by a same process as the second electrode of adjacent pixel area PA. For example, the second electrode 330 of each pixel area PA can be formed simultaneously with the second electrode 330 of adjacent pixel area PA. The second electrode 330 of each pixel area PA can be in direct contact with the second electrode 330 of adjacent pixel area PA. For example, the bank insulating layer 160 can overlap a portion of the second electrode 330. Thus, in the display apparatus according to the embodiment of the present disclosure, a process of forming the second electrode 330 in each pixel area PA can be simplified.

The image realized by the pixel areas PA can include various colors. For example, the light emitted from the light-emitting device 300 of each pixel area PA can display a different color from the light emitted from the light-emitting device 300 of adjacent pixel area PA. For example, the light-emitting device 300 of each pixel area PA can be one of a red light-emitting device emitting light displaying red color, a green light-emitting device emitting light displaying green color, and a blue light-emitting device emitting light displaying blue color. Some of the light-emitting unit 320 in each pixel area PA can be spaced apart from the light-emitting unit 320 of adjacent pixel area PA. For example, the light-emitting unit 320 of each pixel area PA can include an end disposed on the bank insulating layer 160.

An encapsulation structure 400 can be disposed on the light-emitting device 300 of each pixel area PA. The encapsulation structure 400 can prevent damage of the light-emitting device 300 in each pixel area PA due to the external impact and moisture. The encapsulation structure 400 can have a multi-layer structure. For example, the encapsulation structure 400 can include a first encapsulating layer 410, a second encapsulating layer 420 and a third encapsulating layer 430, which are sequentially stacked on the second electrode 330 of each pixel area PA.

The first encapsulating layer 410, the second encapsulating layer 420 and the third encapsulating layer 430 can include an insulating material. The second encapsulating layer 420 can include a different material from the first encapsulating layer 410 and the third encapsulating layer 430. The second encapsulating layer 420 can include a material having higher fluidity than the first encapsulating layer 410 and the third encapsulating layer 430. For example, the first encapsulating layer 410 and the third encapsulating layer 430 can be an inorganic insulating layer including an inorganic insulating material, and the second encapsulating layer 420 can be an organic insulating layer including an organic insulating material. A thickness difference due to the light-emitting device 300 of each pixel area PA can be removed by the second encapsulating layer 420. The second encapsulating layer 420 can have a greater thickness than the first encapsulating layer 410 and the third encapsulating layer 430. For example, an upper surface of the encapsulation structure 400 opposite to the device substrate 100 can be a flat surface. The upper surface of the encapsulation structure 400 can be parallel to the upper surface of the device substrate 100.

As shown in FIGS. 1, 3 and 4, at least one encapsulation dam 105 can be disposed on the bezel area BZ. The encapsulation dam 105 can block the flow of the second encapsulating layer 420, which is an organic insulating layer. For example, the encapsulation dam 105 can surround the active area AA. The encapsulation dam 105 can extend along between the active area AA and the gate driver GD. The encapsulation dam 105 can extend along between the active area AA and the pad portion PAD. Thus, in the display apparatus according to the embodiment of the present disclosure, the gate driver GD and/or the pad portion PAD cannot be covered by the second encapsulating layer 420 by the encapsulation dam 105. Therefore, in the display apparatus according to the embodiment of the present disclosure, the movement of pads disposed in the pad portion PAD and components formed in the gate driver GD due to the flow of the second encapsulating layer 420 can be prevented. That is, in the display apparatus according to the embodiment of the present disclosure, signal distortion due to the second encapsulating layer 420 can be prevented.

The encapsulation dam 105 can include an insulating material. The encapsulation dam 105 can have a multi-layer structure. For example, the encapsulation dam 105 can include a first encapsulating pattern 105a and a second encapsulating pattern 105b disposed on the first encapsulating pattern 105a. The encapsulation dam 105 can be formed using a process of forming the driving circuit DC and the light-emitting device 300 in each pixel area PA. For example, the first encapsulating pattern 105a can include a same material as the planarization layer 150, and the second encapsulating pattern 105b can include a same material as the bank insulating layer 160. The encapsulation dam 105 can be disposed on the device passivation layer 140. The encapsulation dam 105 can be spaced apart from the planarization layer 150 and the bank insulating layer 160. Thus, in the display apparatus according to the embodiment of the present disclosure, decrease of process efficiency due to a process of forming the encapsulation dam 105 can be prevented, and the flow of the second encapsulating layer 420 can be effectively prevented by a space between the encapsulation dam 105 and the planarization layer 150. The third encapsulating layer 430 can be in direct contact with the first encapsulating layer 410 on an upper surface of the encapsulation dam 105 opposite to the device substrate 100.

A barrier structure 500 can be disposed on the encapsulation structure 400 of the active area AA. The barrier structure 500 can limit a direction in which the light emitted from the light-emitting device 300 of each pixel area PA travels. The barrier structure 500 can have a multi-layer structure. For example, the barrier structure 500 can have a stacked structure of a first barrier pattern 510 and a second barrier pattern 520.

The first barrier pattern 510 can be disposed close to the encapsulation structure 400. For example, the first barrier pattern 510 can be in direct contact with the upper surface of the encapsulation structure 400. The first barrier pattern 510 can be disposed outside the emission area EA defined in the each pixel area PA. For example, the first barrier pattern 510 can overlap the bank insulating layer 160. The second barrier pattern 520 can be disposed on the first barrier pattern 510. The second barrier pattern 520 can overlap the first barrier pattern 510. For example, the emission area EA defined in each pixel area PA cannot overlap the first barrier pattern 510 and the second barrier pattern 520. The first barrier pattern 510 can be disposed between the bank insulating layer 160 and the second barrier pattern 520.

The first barrier pattern 510 and the second barrier pattern 520 can include a material capable of absorbing and/or reflecting light. For example, the first barrier pattern 510 and the second barrier pattern 520 can include a black dye, such as carbon black. The second barrier pattern 520 can include a same material as the first barrier pattern 510. Thus, in the display apparatus according to the embodiment of the present disclosure, the light emitted from the light-emitting device 300 of each pixel area PA toward adjacent pixel area PA can be blocked by the first barrier pattern 510 or the second barrier patter 520. Therefore, in the display apparatus according to the embodiment of the present disclosure, a viewing angle of the light emitted from each pixel area PA can be limited by the barrier structure 500.

The second barrier pattern 520 can be spaced apart from the first barrier pattern 510. For example, an optical insulating layer 610 can be disposed between the first barrier pattern 510 and the second barrier pattern 520. The optical insulating layer 610 can cover the first barrier pattern 510. The optical insulating layer 610 can have a greater thickness than the first barrier pattern 510 and the second barrier pattern 520. For example, a thickness difference due to the first barrier pattern 510 can be removed by the optical insulating layer 610. The second barrier pattern 520 can be in direct contact with an upper surface of the optical insulating layer 610 opposite to the device substrate 100. The optical insulating layer 610 can include an insulating material. The optical insulating layer 610 can include a transparent material. For example, the optical insulating layer 610 can include an organic insulating material. An optical path passing through an opening of the barrier structure 500 can be proportion to a thickness of the optical insulating layer 610. For example, in the display apparatus according to the embodiment of the present disclosure, a focal distance of the light emitted from the light-emitting device 300 of each pixel area PA and passing through an opening of the first barrier pattern 510 and an opening of the second barrier pattern 520 can be adjusted by the optical insulating layer 610.

An optical passivation layer 620 can be disposed on the optical insulating layer 610. The optical passivation layer 620 can prevent damage of the upper surface of the optical insulating layer 610 due to a subsequence process. For example, the optical passivation layer 620 can be in direct contact with the upper surface of the optical insulating layer 610 exposed by the second barrier pattern 520. The second barrier pattern 520 can be covered by the optical passivation layer 620. The optical passivation layer 620 can include an insulating material. The optical passivation layer 620 can include a harder material than the optical insulating layer 610. For example, the optical passivation layer 620 can be an inorganic insulating layer including an inorganic insulating material. Thus, in the display apparatus according to the embodiment of the present disclosure, scattering of light due to a surface roughness of a portion of the optical insulating layer 610 overlapping with each pixel area PA can be prevented. In one embodiment, the optical insulating layer 610 can be disposed only on the active area AA. For example, the optical passivation layer 620 can be in direct contact with the third encapsulating layer 430 on the bezel area BZ.

An optical structure 700 can be disposed on the optical passivation layer 620 of the active area AA. The optical structure 700 can include pixel lenses 701 and a lens passivation layer 702. The pixel lenses 701 can be disposed on the pixel areas PA. For example, the light emitted from each pixel area PA and passing through the barrier structure 500 can be condensed by the pixel lens 701 of the corresponding pixel area PA. Thus, in the display apparatus according to the embodiment of the present disclosure, a narrow viewing angle can be realized. For example, the image realized by the display apparatus according to the embodiment of the present disclosure cannot be recognized by peoples around the user. The pixel lens 701 of each pixel area PA can have a larger size than the emission area EA defined in the corresponding pixel area PA. For example, the pixel lens 701 of each pixel area PA can be disposed in one of regions defined by the second barrier pattern 520. Therefore, in the display apparatus according to the embodiment of the present disclosure, light leakage and color mixing can be prevented. A lower surface of the pixel lens 701 toward the device substrate 100 in each pixel area PA can be in direct contact with the optical passivation layer 620.

The lens passivation layer 702 can prevent damage of the pixel lenses 701 due to the external impact. For example, the lens passivation layer 702 can completely cover the pixel lenses 701. A refractive index of the lens passivation layer 702 can be smaller than a refractive index of each pixel lens 701. Thus, in the display apparatus according to the embodiment of the present disclosure, light introducing the pixel lens 701 of each pixel area PA can be refracted toward a center of the corresponding pixel area PA at a boundary between the corresponding pixel lens 701 and the lens passivation layer 702. The lens passivation layer 702 can include an insulating material. For example, the lens passivation layer 702 can include an organic insulating material. A thickness difference due to the pixel lenses 701 can be removed by the lens passivation layer 702. For example, an upper surface of a portion of the lens passivation layer 702 overlapping with the active area AA can be a flat surface.

A cross-section of each pixel lens 701 can be a semicircular shape. The pixel lenses 701 can be formed by a reflow process. For example, in the display apparatus according to the embodiment of the present disclosure, a process of forming the pixel lenses 701 can include a step of forming a lens formation material layer on the optical passivation layer 620, a step of forming lens patterns on the pixel areas PA by patterning the lens formation material layer, and a step of reflowing the lens pattern of each pixel area PA.

A lens dam 750 can be disposed on the optical passivation layer 620 of the bezel area BZ. The lens dam 750 can surround the active area AA. The lens dam 750 can block the flow of the lens passivation layer 702. For example, the lens passivation layer 702 can be disposed in a region defined by the lens dam 750. The lens dam 750 can surround the lens passivation layer 702. The lens dam 750 can be disposed on a same layer as the optical structure 700. For example, the lens dam 750 can be disposed between the active area AA and the encapsulation dam 105. The lens dam 750 can be disposed on a portion of the second encapsulating layer 420. Thus, in the display apparatus according to the embodiment of the present disclosure, the flow of the lens passivation layer 702 can be effectively blocked by the lens dam 750.

The lens dam 750 can include an insulating material. The lens dam 750 can be formed using a process of forming the pixel lenses 701. For example, the lens dam 750 can include a same material as the pixel lenses 701. The lens dam 750 can be formed by a reflow process. The lens dam 750 can have a different shape from each pixel lens 701. For example, a cross-section of the lens dam 750 can be an elliptical shape. The maximum thickness of the lens dam 750 can be smaller than the maximum thickness of each pixel lens 701.

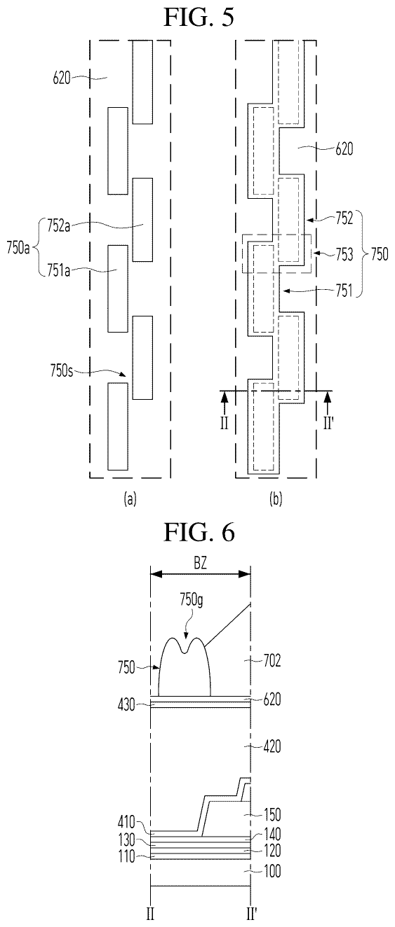

FIG. 5(a) is a view showing a plane shape of a lens dam before a reflow process in the display apparatus according to the embodiment of the present disclosure, and FIG. 5(b) is a view showing the plane shape of the lens dam after the reflow process in the display apparatus according to the embodiment of the present disclosure. FIG. 6 is a view taken along II-II′ of FIG. 5 according to an embodiment.

Referring to FIGS. 1 and 4 to 6, in the display apparatus according to the embodiment of the present disclosure, a process of forming the lens dam 750 can include a step of forming a preliminary dam patterns 750a including a plurality of slits 750s on the optical passivation layer 620 of the bezel area BZ, and a step of removing the plurality of slits 750s by reflowing the preliminary dam patterns 750a. Thus, in the display apparatus according to the embodiment of the present disclosure, loss and deformation of the lens dam 750 in a process of forming the pixel lenses 701 and/or a process of forming the lens passivation layer 702 can be reduced.

The preliminary dam patterns 750a can include first preliminary patterns 751a and second preliminary patterns 752a alternately disposed with the first preliminary patterns 751a. The second preliminary patterns 752a can include a same material as the first preliminary patterns 751a. Each of the first preliminary patterns 751a and each of the second preliminary patterns 752a can have a bar shape extending in a first direction. The second preliminary patterns 752a can be spaced apart from the first preliminary patterns 751a in a second direction perpendicular to the first direction. For example, the plurality of slits 750s can be a spaced region between the first preliminary patterns 751a and the second preliminary patterns 752a.

Each of the second preliminary patterns 752a can have a same size as each first preliminary pattern 751a. For example, a length of each second preliminary pattern 752a in the first direction can be a same as a length of each first preliminary pattern 751a in the first direction, and a width of each second preliminary pattern 752a in the second direction can be a same as a width of each first preliminary pattern 751a in the second direction. An end of each first preliminary pattern 751a can be disposed side by side with an end of one of the second preliminary patterns 752a in the second direction, and the other end of each first preliminary pattern 751a can be disposed side by side with an end of one of the remaining second preliminary patterns 752a in the second direction. An end of each second preliminary pattern 752a can be disposed side by side with an end of one of the first preliminary patterns 751a in the second direction, and the other end of each second preliminary pattern 752a can be disposed side by side with an end of one of the remaining first preliminary patterns 751a in the second direction. For example, the plurality of slits 750s can be formed between a portion of each first preliminary pattern 751a and a portion of each second preliminary pattern 752a, which are disposed side by side in the second direction.

The lens dam 750 can be formed simultaneously with the pixel lenses 701. For example, the first preliminary patterns 751a and the second preliminary patterns 752a can include a same material as the lens formation material layer. The first preliminary patterns 751a and the second preliminary patterns 752a can be reflowed by a reflow process of the lens patterns for the formation of the pixel lenses 701. Thus, in the display apparatus according to the embodiment of the present disclosure, loss and deformation of the lens dam 750 in a process of patterning the lens formation material layer for the formation of the lens patterns can be prevented. For example, in the display apparatus according to the embodiment of the present disclosure, since the developer used in a process of patterning the lens formation material layer can move through the slits 750s of the preliminary dam patterns 750a, the loss and the deformation of the lens dam 750 due to the movement of the developer can be prevented. And, in the display apparatus according to the embodiment of the present disclosure, decrease of the process efficiency due to a process of forming the lens dam 750 can be prevented. Therefore, in the display apparatus according to the embodiment of the present disclosure, the loss and the deformation of the lens dam 750 due to a process of forming the pixel lenses 701 and/or a process of forming the lens passivation layer 702 can be prevented, without decrease of the process efficiency.

The lens dam 750 formed by a reflow process of the preliminary dam patterns 750a can include first dam regions 751, second dam regions 752 and third dam regions 753. Each of the first dam regions 751 can be a region formed by reflowing a portion of each first preliminary pattern 751a that does not overlap the second preliminary patterns 752a. For example, each of the first dam regions 751 can have a bar shape extending in the first direction. Each of the second dam regions 751 can be a region formed by reflowing a portion of each second preliminary pattern 752a that does not overlap the first preliminary patterns 751a. For example, each of the second dam regions 752 can have a bar shape extending in the first direction. Each of the second dam regions 752 can have a same size as each first dam region 751. For example, a length of each second dam region 752 in the first direction can be a same as a length of each first dam region 751 in the first direction, and a width of each second dam region 752 in the second direction can be a same as a width of each first dam region 751 in the second direction. The second dam regions 752 can be alternately disposed with the first dam regions 751 in the second direction.

The third dam regions 753 can be disposed between the first dam regions 751 and the second dam regions 752. Each of the third dam regions 753 can be a region formed by reflowing a portion of each first preliminary pattern 751a and a portion of each second preliminary pattern 752a that are disposed side by side in the second direction. For example, each of the third dam regions 753 can be in direct contact with an end of one of the first dam regions 751 and an end of one of the second dam regions 752. Thus, in the display apparatus according to the embodiment of the present disclosure, the flow of the lens passivation layer 702 can be blocked by the lens dam 750. The slits 750s can be filled by a process of reflowing the first preliminary patterns 751a and the second preliminary patterns 752a. The lens dam 750 can have a relatively small thickness between the first preliminary patterns 751a and the second preliminary patterns 752a. For example, an upper surface of each third dam region 753 opposite to the device substrate 100 can include a groove 750g. A length of each third dam region 753 in the second direction can be greater than a width of each first dam region 751 in the second direction and a width of each second dam region 752 in the second direction. For example, in the display apparatus according to the embodiment of the present disclosure, a first side of the lens dam 750 toward the active area AA and a second side of the lens dam 750 opposite to the first side can have a concave-convex shape. The second side of the lens dam 750 can extend parallel to the first side of the lens dam 750. For example, a plane of the lens dam 750 can have a concave-convex shape. A length of each third dam region 753 in the first direction can be different from a length of each first dam region 751 in the first direction and a length of each second dame region 752 in the first direction.

Accordingly, the display apparatus according to the embodiment of the present disclosure can include the barrier structure 500, the optical insulating layer 610, the optical passivation layer 620, the pixel lenses 701, the lens passivation layer 702 and the lens dam 750 disposed on the encapsulation structure 400 covering the light-emitting device 300 of each pixel area PA, wherein a process of forming the lens dam 750 can include a step of forming the preliminary dam patterns 750a including the slits 750s and a step of removing the slits 750s by reflowing the preliminary dam patterns 750a, wherein a reflow process of the preliminary dam patterns 750a can be performed simultaneously with a reflow process of the lens patterns for the formation of the pixel lenses 701, such that a plane of the lens dam 750 can have a concave-convex shape. Thus, in the display apparatus according to the embodiment of the present disclosure, the loss and/or the deformation of the lens dam 750 due to a process of forming the pixel lenses 701 and a process of forming the lens passivation layer 702 can be prevented, and the flow of the lens passivation layer 702 can be blocked by the lens dam 750. Therefore, in the display apparatus according to the embodiment of the present disclosure, each of the pixel lenses 701 can be completely covered by the lens passivation layer 702. That is, in the display apparatus according to the embodiment of the present disclosure, damage of the pixel lenses 701 due to the external impact can be prevented, without the decrease of the process efficiency.

The display apparatus according to the embodiment of the present disclosure is described that the driving circuit DC of each pixel area PA can consist of the first thin film transistor TR1, the second thin film transistor TR2 and the storage capacitor Cst. However, in the display apparatus according to another embodiment of the present disclosure, the driving circuit DC of each pixel area PA can include a driving thin film transistor and at least one switching thin film transistor. For example, in the display apparatus according to another embodiment of the present disclosure, the driving circuit DC of each pixel area PA can further include a third thin film transistor capable of initializing the storage capacitor Cst of the corresponding pixel area PA according to the gate signal. The third thin film transistor of each pixel area PA can include a third semiconductor pattern, a third gate electrode, a third drain electrode and a third source electrode. The third semiconductor pattern of each pixel area PA can include a semiconductor material. The third gate electrode of each pixel area PA can be electrically connected to the corresponding gate line GL. The third drain electrode of each pixel area PA can be electrically connected to an initializing line applying an initializing signal. The third source electrode of each pixel area PA can be electrically connected to the storage capacitor Cst of the corresponding pixel area PA. Thus, in the display apparatus according to another embodiment of the present disclosure, the degree of freedom in configuring each driving circuit DC can be improved.

In the display apparatus according to the embodiment of the present disclosure, the location and the electric connection of the first drain electrode, the first source electrode, the second drain electrode 225 and the second source electrode 227 in each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC can be electrically connected to the first drain electrode of the corresponding driving circuit DC. Thus, in the display apparatus according to another embodiment of the present disclosure, the degree of freedom in the configuration of each driving circuit DC and the type of each thin film transistor TR1 and TR2 can be improved.

In the display apparatus according to another embodiment of the present disclosure, color filters can be disposed on a path of light emitted from the light-emitting device 300 of each pixel area PA. For example, in the display apparatus according to another embodiment of the present disclosure, the color filters can be disposed between the encapsulation structure 400 and the optical insulating layer 610. Each of the color filters can overlap the emission area

EA defined in one of the pixel areas PA. The thickness deference due to the color filters can be removed by the optical insulating layer 610. The light passing through the color filter of each pixel area PA can display a same color as the light emitted from the light-emitting device 300 of the corresponding pixel area PA. Thus, in the display apparatus according to another embodiment of the present disclosure, color reproduction can be improved.

The display apparatus according to the embodiment of the present disclosure is described that the light emitted from the light-emitting device 300 of each pixel area PA can display a different color from the light emitted from the light-emitting device 300 of adjacent pixel area PA. However, in the display apparatus according to another embodiment of the present disclosure, the light emitted from the light-emitting device 300 of each pixel area PA can display a same color as the light emitted from the light-emitting device 300 of adjacent pixel area PA. For example, in the display apparatus according to the embodiment of the present disclosure, white light can be emitted from the light-emitting device 300 of each pixel area PA. That is, in the display apparatus according to another embodiment of the present disclosure, the image having various colors can be realized by the color filters disposed on the pixel areas PA. For example, the light-emitting unit 320 of each pixel area PA can have a stacked structure same as the light-emitting unit 320 of adjacent pixel area PA. The light-emitting unit 320 of each pixel area PA can be formed by a same process as the light-emitting unit 320 of adjacent pixel area PA. For example, the light-emitting unit 320 of each pixel area PA can be formed simultaneously with the light-emitting unit 320 of adjacent pixel area PA. Thus, in the display apparatus according to another embodiment of the present disclosure, a process of forming the light-emitting unit 320 in each pixel area PA can be simplified. Therefore, in the display apparatus according to another embodiment of the present disclosure, the process efficiency can be improved.

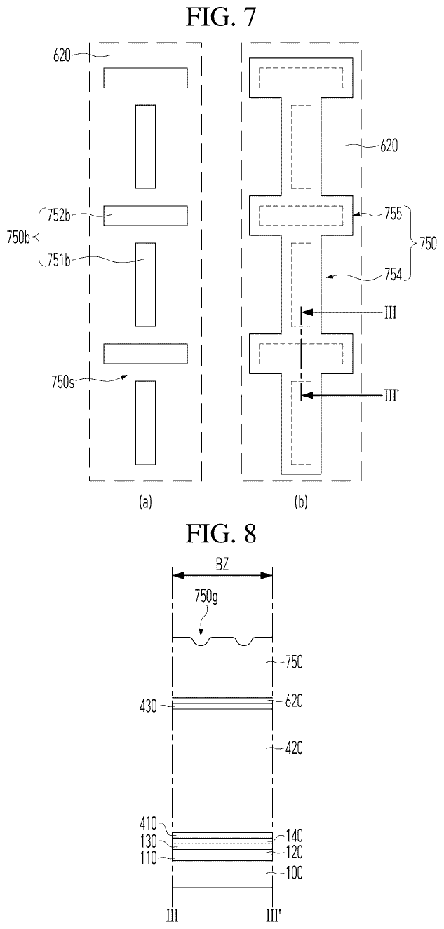

The display apparatus according to the embodiment of the present disclosure is described that the preliminary dam patterns 750a can include the first preliminary patterns 751a and the second preliminary patterns 752a spaced apart from the first preliminary patterns 751a in the second direction. However, in the display apparatus according to another embodiment of the present disclosure, the second preliminary patterns 752a can be formed at various locations. For example, in the display apparatus according to another embodiment of the present disclosure, the preliminary dam patterns 750b can include the first preliminary patterns 751b and the second preliminary patterns 752b disposed between the first preliminary patterns 751b, as shown in FIGS. 7 and 8. Each of the first preliminary patterns 751b can have a bar shape extending in the first direction. Each of the second preliminary patterns 752b can have a bar shape extending in the second direction. A size of each second preliminary pattern 752b can have a same as a size of each first preliminary pattern 751b. For example, a length of each second preliminary pattern 752b in the first direction can be a same as a length of each first preliminary pattern 751b in the second direction, and a length of each second preliminary pattern 752b in the second direction can be a same as a length of each first preliminary pattern 751b in the first direction. The second preliminary patterns 752b can be spaced apart from the first preliminary patterns 751b. For example, the slits 750s of the preliminary dam patterns 750b can be disposed between the first preliminary patterns 751b and the second preliminary patterns 752b. Thus, in the display apparatus according to another embodiment of the present disclosure, the lens dam 750 formed by a reflow process of the preliminary dam patterns 750b can include first dam regions 754 and second dam regions 755 disposed between the first dam regions 754.

Each of the first dam regions 754 can have a bar shape extending in the first direction. Each of the second dam regions 755 can have a bar shape extending in the second direction. For example, a plane of the lens dam 750 can have a shape in which first regions and second regions having a wider width than the first regions are alternately repeated. A size of each second dam region 755 can be a same as a size of each first dam region 754. For example, a length of each second dam region 755 in the first direction can be a same as a length of each first dam region 754 in the second direction, and a length of each second dam region 755 in the second direction can be a same as a length of each first dam region 754 in the first direction. The first side of the lens dam 750 toward the active area AA can have a shape symmetrical to the second side of the lens dam 750 opposite to the first side. The slits 750s can be filled by a reflow process of the first preliminary patterns 751b and the second preliminary patterns 752b. The lens dam 750 can have a relatively small thickness between the first preliminary patterns 751b and the second preliminary patterns 752b. The grooves 750g disposed side by side in the first direction can be disposed at the upper surface of the lens dam 750 opposite to the device substrate 100. Thus, in the display apparatus according to another embodiment of the present disclosure, the degree of freedom for the shape of the preliminary dam patterns 750b and the lens dam 750 can be improved.

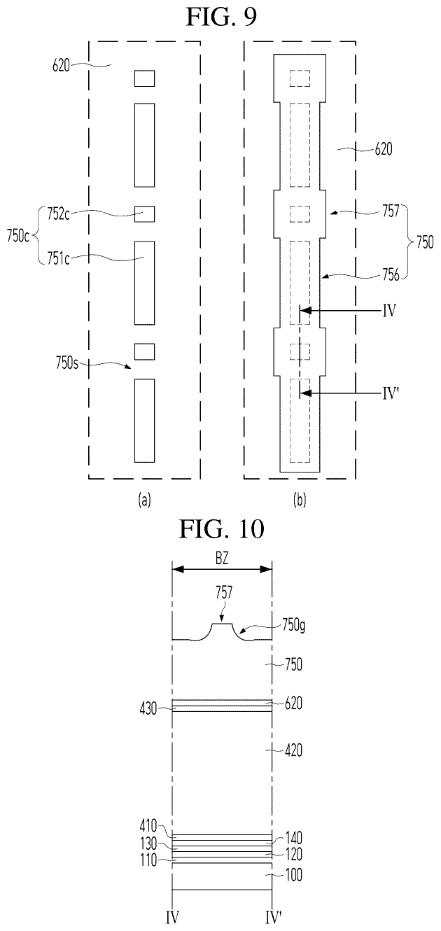

The display apparatus according to the embodiment of the present disclosure is described that each of the second preliminary patterns 752a can have a same size as each first preliminary pattern 751a. However, in the display apparatus according to another embodiment of the present invention, each of the second preliminary patterns 752a can have a different size from each first preliminary pattern 751a. For example, in the display apparatus according to another embodiment of the present disclosure, the preliminary dam patterns 750c can include the first preliminary patterns 751c having a bar shape extending in the first direction and the second preliminary patterns 752c disposed between the first preliminary patterns 751c, wherein a length of each second preliminary patterns 752c in the second direction can be a same as a length of each first preliminary pattern 751c in the second direction, and wherein a length of each second preliminary patterns 752c in the first direction can be smaller than a length of each first preliminary pattern 751c in the first direction, as shown in FIGS. 9 and 10. The slits 750s of the preliminary dam patterns 750c can be disposed between the first preliminary patterns 751c and the second preliminary patterns 752c. A plane of each second preliminary pattern 752c can have a square shape. For example, a length of each second preliminary pattern 752c in the second direction can be a same as a length of each first preliminary pattern 751c in the first direction. A thickness of each second preliminary pattern 752c can be greater than a thickness of each first preliminary pattern 751c. Thus, in the display apparatus according to another embodiment of the present disclosure, the lens dam 750 formed by a reflow process of the preliminary dam patterns 750c can include first dam regions 756 and second dam regions 757 disposed between the first dam regions 756, wherein a thickness of each second dam region 757 can be greater than a thickness of each first dam region 756. Therefore, in the display apparatus according to another embodiment of the present disclosure, an area occupied by the lens dam 750 can be minimized. That is, in the display apparatus according to another embodiment of the present disclosure, an increase in the size of the bezel area BZ due to the lens dam 750 can be reduced or minimized, and the loss and/or the deformation of the lens dam 750 due to a process of forming the pixel lenses and/or a process of forming the lens passivation layer can be prevented, without decrease of process efficiency.

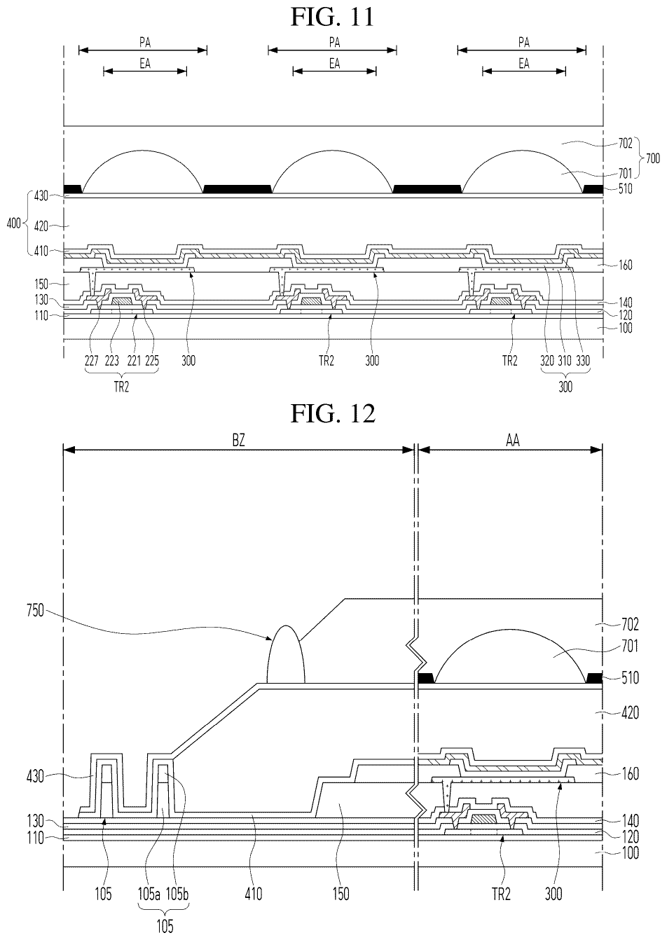

The display apparatus according to the embodiment of the present disclosure is described that the optical insulating layer 610 and the optical passivation layer 620 can be disposed between the encapsulation structure 400 and the optical structure 700. However, in the display apparatus according to another embodiment of the present disclosure, the barrier structure 500 can have a single-layer structure. For example, in the display apparatus according to another embodiment of the present disclose, the pixel lenses 701 can be disposed in regions defined by the first barrier patterns 510, the lens passivation layer 702 can cover the first barrier pattern 510 and the pixel lenses 701, and the lens dam 750 can be in direct contact with the third encapsulating layer 430 of the bezel area BZ, as shown in FIGS. 11 and 12. The lens dam 750 formed by a reflow process can have a high bonding force with the lower layer. That is, in the display apparatus according to another embodiment of the present disclosure, the degree of freedom for the lower layer of the lens dam 750 can be improved. Therefore, in the display apparatus according to another embodiment of the present disclosure, the degree of freedom for a stacked structure in the active area AA can be improved.

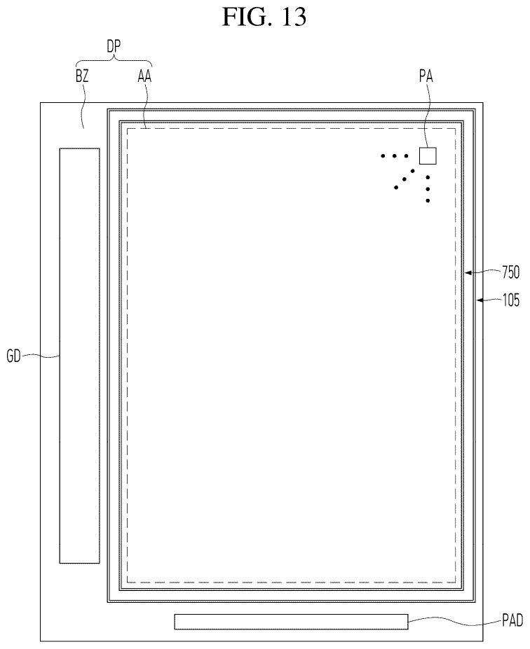

The display apparatus according to the embodiment of the present disclosure is described that a single lens dam 750 can be formed. However, in the display apparatus according to another embodiment of the present disclosure, a plurality of lens dam 750 can be disposed between the active area AA and the encapsulation dam 105. For example, in the display apparatus according to another embodiment of the present disclosure, the active area AA can be surrounded by two lens dams 750 extending parallel to each other, as shown in FIG. 13. The two lens dams 750 can include a same material. The two lens dams 750 can be formed by a same process. For example, the two lens dams 750 can be formed simultaneously. Thus, in the display apparatus according to another embodiment of the present disclosure, the loss and/or the deformation of the lens dam 750 due to a process of forming the pixel lenses and a process of forming the lens passivation layer can be prevented, and the flow of the lens passivation layer can be effectively blocked.

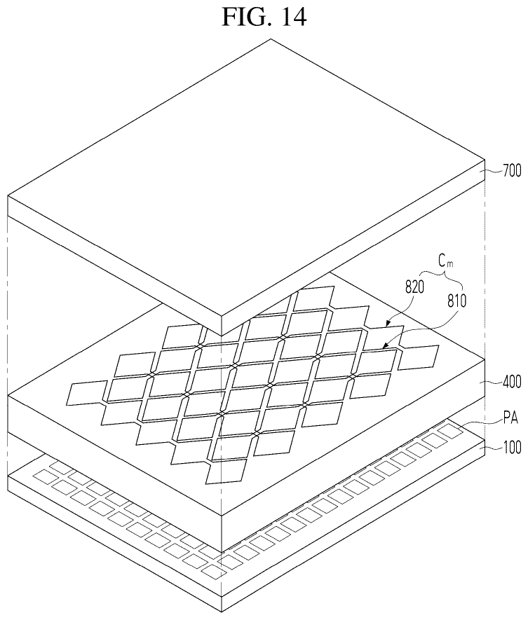

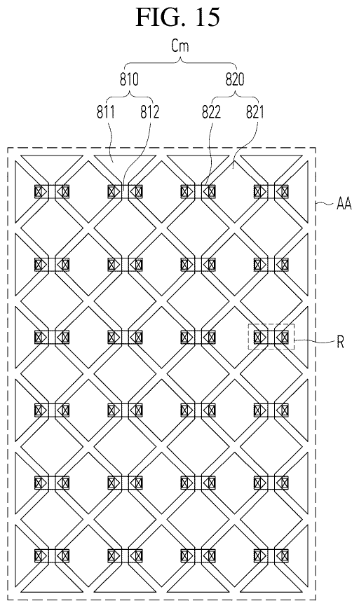

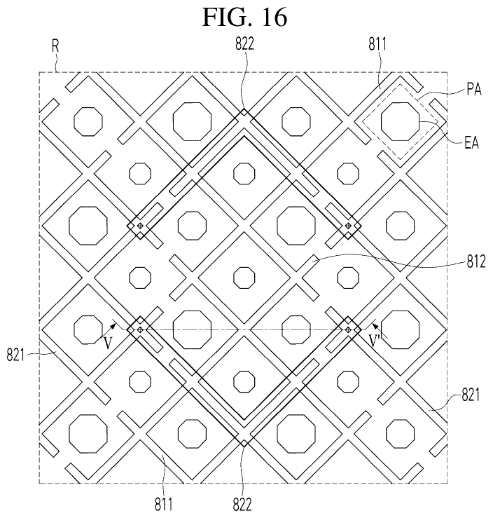

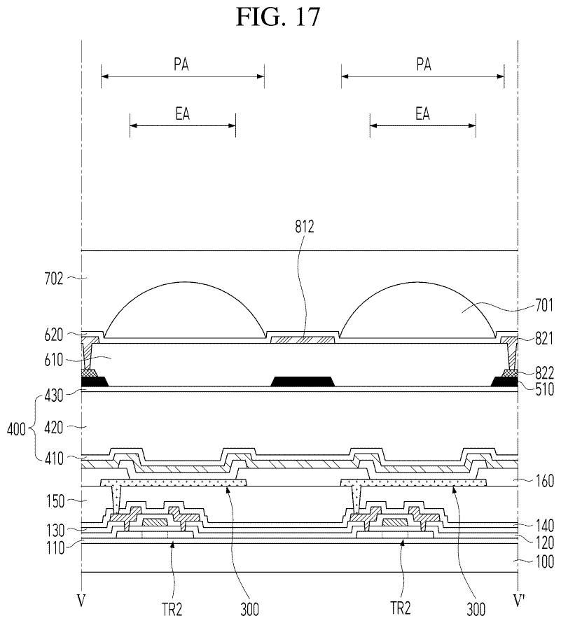

The display apparatus according to another embodiment of the present disclosure can further include a touch sensor for sensing a touch of the user and/or a tool. For example, in the display apparatus according to another embodiment of the present disclosure, the touch sensor Cm can be disposed on the encapsulation structure 400 and the optical structure 700, as shown in FIGS. 14 to 17. The touch sensor Cm can sense the presence or absence of a touch and a touch position by a change of the mutual capacitance. For example, the touch sensor Cm can include driving touch lines 810 in which a touch driving signal is applied and sensing touch lines 820 in which a touch sensing signal is applied.

Each of the driving touch lines 810 can include first touch electrodes 811 and first bridge electrodes 812. The first bridge electrodes 812 can electrically connect between the first touch electrodes 811. For example, each of the driving touch lines 810 can include the first touch electrodes 811 electrically connected in a direction by the first bridge electrodes 812. Each of the sensing touch lines 820 can include second touch electrodes 821 and second bridge electrodes 822. The second touch electrodes 821 can be disposed between the first touch electrodes 811. For example, the first touch electrodes 811 and the second touch electrodes 821 can be alternately arranged. Thus, the display apparatus according to another embodiment of the present disclosure can sense the touch of the user and/or the tool by using the driving touch lines 810 and the sensing touch lines 820.

The second bridge electrodes 822 can electrically connect between the second touch electrodes 821. The second touch electrodes 821 can be connected by the second bridge electrodes 822 in a direction perpendicular to the first touch electrodes 811. For example, each of the sensing touch lines 820 can cross the driving touch lines 810. Each of the second bridge electrodes 822 can intersect one of the first bridge electrodes 812. The second bridge electrodes 822 can be disposed on a layer different from the first bridge electrodes 812. For example, the second bridge electrodes 822 may be disposed on the first barrier pattern 510, the optical insulating layer 610 can cover the first barrier pattern 510 and the second bridge electrodes 822, and the first touch electrodes 811, the second touch electrodes 821 and the first bridge electrodes 812 can be disposed on the optical insulating layer 610. The optical passivation layer 620 can cover the first touch electrodes 811, the second touch electrodes 821 and the first bridge electrodes 812.

The first touch electrodes 811, the first bridge electrodes 812, the second touch electrodes 821 and the second bridge electrodes 822 can include a conductive material. The first touch electrodes 811, the first bridge electrodes 812, the second touch electrodes 821 and the second bridge electrodes 822 can include a material having a relatively low resistance. For example, the first touch electrodes 811, the first bridge electrodes 812, the second touch electrodes 821 and the second bridge electrodes 822 can include a metal, such as copper (Cu), molybdenum (Mo), titanium (Ti) and tantalum (Ta).

The touch sensor Cm can be disposed in the active area AA. The first touch electrodes 811, the first bridge electrodes 812, the second touch electrodes 821, and the second bridge electrodes 822 can be disposed outside the emission area EA defined in each pixel area PA. For example, the first touch electrodes 811, the first bridge electrodes 812, the second touch electrodes 821, and the second bridge electrodes 822 can overlap the bank insulating layer 160. The first barrier pattern 510 can be disposed between the bank insulating layer 160 and the second bridge electrodes 822. Thus, in the display apparatus according to another embodiment of the present disclosure, the first touch electrodes 811, the first bridge electrodes 812, the second touch electrodes 821, and the second bridge electrodes 822 can limit the direction of light emitted from the emission area EA of each pixel area PA. For example, the first touch electrodes 811, the first bridge electrodes 812, the second touch electrodes 821, and the second bridge electrodes 822 disposed on the optical insulating layer 610 may function as a second barrier pattern. Therefore, in the display apparatus according to another embodiment of the present disclosure, the image having a narrow viewing angle may be realized by using the first barrier pattern 510, the touch sensor Cm and the pixel lenses 701, and the damage of the pixel lenses 701 due to the external impact may be prevented.

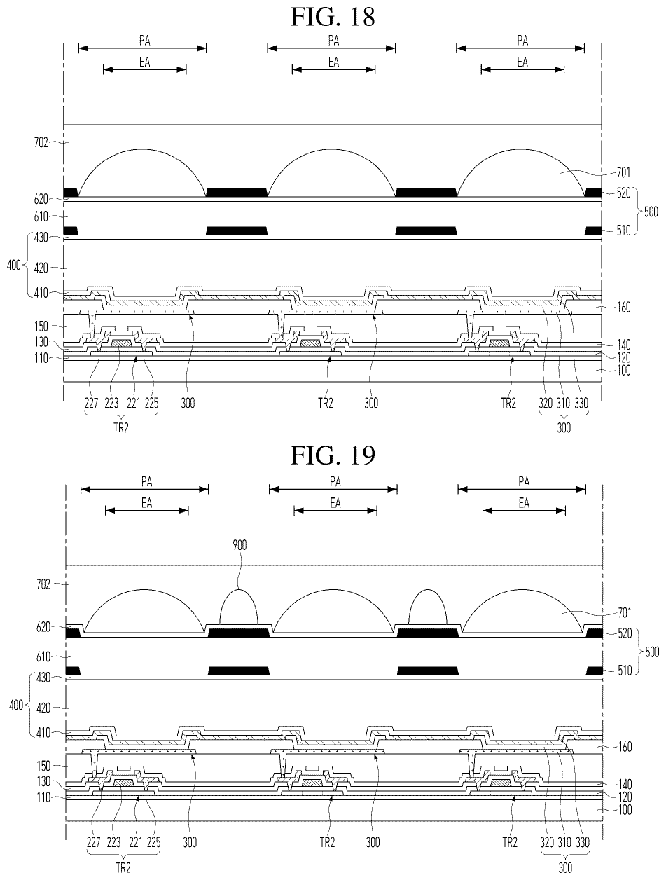

The display apparatus according to the embodiment of the present disclosure is described that the second barrier pattern 520 can be covered by the optical passivation layer 620. However, in the display apparatus according to another embodiment of the present disclosure, the optical passivation layer 620 can extend along between the optical insulating layer 610 and the second barrier pattern 520, as shown in FIG. 18. The second barrier pattern 520 can be covered by the lens passivation layer 702. Thus, in the display apparatus according to another embodiment of the present disclosure, damage of the upper surface of the optical insulating layer 610 due to a process of forming the second barrier pattern 520 can be prevented. That is, in the display apparatus according to another embodiment of the present disclosure, efficiency of the light emitted from the emission area EA of each pixel area PA can be improved. Therefore, in the display apparatus according to another embodiment of the present disclosure, quality of the image provided to the user by the pixel areas PA can be improved, and power consumption can be reduced.

In the display apparatus according to another embodiment of the present disclosure, at least one lens spacer 900 may be disposed between the pixel lenses 701. For example, in the display apparatus according to another embodiment of the present disclosure, the lens spacer 900 can be disposed on the optical passivation layer 620, as shown in FIG. 19. The lens spacer 900 can overlap the first barrier pattern 510 and the second barrier pattern 520. For example, the lens spacer 900 can overlap the bank insulating layer 160. The lens spacer 900 can be formed using a process of forming the pixel lenses 701. For example, the lens spacer 900 can include a same material as the pixel lenses 701. The lens spacer 900 can have a different shape from the pixel lenses 701. For example, a cross-section of the lens spacer 900 can have an elliptical shape. A maximum thickness of the lens spacer 900 can be different from a maximum thickness of each pixel lens 701. Thus, in the display apparatus according to another embodiment of the present disclosure, the upper surface of the lens passivation layer 702 between the pixel lenses 701 can be maintained at a constant level by the lens spacer 900. For example, in the display apparatus according to another embodiment of the present disclosure, the flatness of the upper surface of the lens passivation layer 702 can be improved by the lens spacer 900. That is, in the display apparatus according to another embodiment of the present disclosure, distortion of the image due to differences in a position where light generated by the light-emitting device 300 of each pixel area PA is emitted can be prevented by the lens spacer 900. Therefore, in the display apparatus according to another embodiment of the present disclosure, the damage of the pixel lenses 701 due to the external impact may be effectively prevented and the quality of the image provided to the user may be improved, without the decrease of the process efficiency.

In the result, the display apparatus according to the embodiments of the present disclosure can comprise the pixel lenses disposed on the encapsulation structure covering the light-emitting devices, the lens passivation layer covering the pixel lenses, and the lens dam surrounding the lens passivation layer, wherein the lens dam can include a first region and a second region having a different width from the first region. Thus, in the display apparatus according to the embodiments of the present disclosure, the loss and the deformation of the lens dam due to a process of forming the pixel lenses and a process of forming the lens passivation layer can be prevented. Thereby, in the display apparatus according to the embodiments of the present disclosure, each of the pixel lenses can completely covered by the lens passivation layer, such that the damage of the pixel lenses due to the external impact can be prevented. And, in the display apparatus according to the embodiments of the present disclosure, production energy can be reduced by process optimization.

What is claimed is:

1. A display apparatus comprising:
a light-emitting device on a pixel area of a device substrate;
an encapsulation structure on the device substrate, the encapsulation structure covering the light-emitting device;
a pixel lens on the encapsulation structure, the pixel lens overlapping with the pixel area;
a lens passivation layer on the encapsulation structure, the lens passivation layer covering the pixel lens; and
a first lens dam on the encapsulation structure, the first lens dam surrounding the lens passivation layer,
wherein the first lens dam further comprises a first dam region, a second dam region, and a third dam region between the first dam region and the second dam region,
wherein each of the first dam region and the second dam region have a bar shape extending in a first direction, and
wherein a length of the third dam region in a second direction perpendicular to the first direction is greater than a length of the first dam region in the second direction and a length of the second dam region in the second direction.

2. The display apparatus according to claim 1, wherein the third dam region includes a same material as the first dam region and the second dam region.

3. The display apparatus according to claim 1, wherein a length of the third dam region in the first direction is different from a length of the first dam region in the first direction and a length of the second dam region in the first direction.

4. The display apparatus according to claim 3, wherein the length of the second dam region in the first direction is a same as the length of the first dam region in the first direction.

5. The display apparatus according to claim 3, wherein the length of the third dam region in the first direction is a same as the length of the first dam region in the second direction and the length of the second dam region in the second direction.

6. The display apparatus according to claim 1, wherein the second dam region is arranged alternately with the first dam region in the second direction.

7. The display apparatus according to claim 1, wherein at least one groove is disposed at an upper surface of the first lens dam opposite to the device substrate.

8. The display apparatus according to claim 1, further comprising a second lens dam disposed on the encapsulation structure, the second lens dam extending parallel to the first lens dam.

9. A display apparatus comprising:
a device substrate including an active area and a bezel area;
light-emitting devices disposed on pixel areas of the active area;
an encapsulation structure on the device substrate, the encapsulation structure covering the light-emitting devices;
pixel lenses on the encapsulation structure, the pixel lenses overlapping with the pixel areas;
a lens dam on the encapsulation structure of the bezel area, the lens dam surrounding the active area; and
a lens passivation layer disposed in a region defined by the lens dam, the lens passivation layer covering the pixel lenses,
wherein a first side of the lens dam toward the active area has a concave-convex shape.

10. The display apparatus according to claim 9, wherein the lens dam includes a same material as the pixel lenses.

11. The display apparatus according to claim 9, wherein a second side of the lens dam opposite to the first side has a concave-convex shape.

12. The display apparatus according to claim 11, wherein the second side of the lens dam is a shape symmetrical to the first side of the lens dam.

13. The display apparatus according to claim 9, further comprising at least one barrier pattern disposed between the encapsulation structure and the pixel lenses,
wherein the barrier pattern is disposed outside an emission area defined in each pixel area.

14. The display apparatus according to claim 13, further comprising a touch sensor disposed between the encapsulation structure and the pixel lenses,
wherein the touch sensor includes touch electrodes overlapping with the barrier pattern.

15. The display apparatus according to claim 13, further comprising at least one lens spacer disposed between the pixel lenses, the lens spacer overlapping with the barrier pattern.

16. The display apparatus according to claim 11, wherein the lens dam includes first dam regions and second dam regions disposed between the first dam regions.

17. The display apparatus according to claim 16, wherein the first dam regions have a bar shape extending in a first direction, and
wherein at both sides of the second dam region, an upper surface of the lens dam opposite to the device substrate has grooves disposed side by side in the first direction.

18. The display apparatus according to claim 17, wherein the second dam regions have a bar shape extending in a second direction perpendicular to the first direction, and
wherein a size of the second dam region is the same as a size of the first dam region.

19. The display apparatus according to claim 16, wherein a thickness of the second dam region is greater than a thickness of the first dam region.
